(19) United States
(12) Patent Application Publication
(10) Pub. No.: US 2017/0345805 A1
(43) Pub. Date: Nov. 30, 2017

(54) PACKAGE INCLUDING STACKED DIE AND PASSIVE COMPONENT

(71) Applicant: STMicroelectronics (Grenoble 2) SAS, Grenoble (FR)

(72) Inventors: Norbert Chevrier, Fontaine (FR); Benoit Besancon, Villard Bonnot (FR); Jean-Michel Riviere, Froges (FR)

(73) Assignee: STMicroelectronics (Grenoble 2) SAS, Grenoble (FR)

(21) Appl. No.: 15/166,726

(22) Filed: May 27, 2016

(51) Int. Cl. H01L 25/16; H01L 25/00; H01L 23/522; H01L 21/768; H01L 23/31; H01L 23/29; H01L 27/02; H01L 23/00

(52) U.S. Cl. CPC H01L 25/16; H01L 27/0251; H01L 25/50; H01L 24/16; H01L 21/76804; H01L 23/3128; H01L 23/293; H01L 21/76879; H01L 23/5226

(57) ABSTRACT

Disclosed herein is an electronic device including a substrate having a conductive area formed thereon. A first molding level is stacked on the substrate. A die is formed on the substrate and within the first molding level. A second molding level is stacked on the first molding level. At least one passive component is within the second molding level. A conductive structure extends between the second molding level and the substrate and electrically couples the at least one passive component to the conductive area.

### TECHNICAL FIELD

This disclosure is related to the field of integrated circuit and electronic device packaging, and, more particularly, is related to designs therefor that incorporate electrostatic discharge (ESD) protection using stacked passive components.

### BACKGROUND

In certain types of devices, such as Internet of Things devices, for reasons of space saving and simplicity, it is desirable to create a single package containing multiple electronic devices, such as dies, together with ESD protection and other components. Such a single package is typically created by mounting the die on a substrate, placing ESD protection devices around the periphery of the die, and then encapsulating the assembly in a block of resin.

While this produces a compact device, there are some applications where the device being even more so compact would be beneficial. For example, for implantable or wearable medical devices, it is desirable to make such a device as compact as possible. Therefore, further development in the area of electronic device packaging is necessary so as to further miniaturize such devices.

### SUMMARY

Disclosed herein is an electronic device including a substrate having a conductive area formed thereon. A first molding level is stacked on the substrate. A die is formed on the substrate and within the first molding level. A second molding level is stacked on the first molding level. At least one passive component is within the second molding level. A conductive structure extends between the second molding level and the substrate and electrically couples the at least one passive component to the conductive area.

Also disclosed herein is a method of making an electronic device that includes forming a conductive area on a substrate, and disposing a die on the substrate. A first molding layer is deposited over the substrate and the die. At least one passive component is disposed on the first molding layer. A conductive structure extending between the at least one passive component and the conductive area is formed. A second molding layer is deposited over the first molding layer, the at least one passive component, and the conductive structure.

### BRIEF DESCRIPTION OF THE DRAWINGS

FIG. 1 is a cross sectional view of a first embodiment of an electronic device in accordance with this disclosure.

FIG. 2 is a cross sectional view of a second embodiment of an electronic device in accordance with this disclosure.

FIG. 3 is a cross sectional view of a third embodiment of an electronic device in accordance with this disclosure.

FIG. 4 is a cross sectional view of a fourth embodiment of an electronic device in accordance with this disclosure.

FIG. 5 is a cross sectional view of a fifth embodiment of an electronic device in accordance with this disclosure that incorporates elements from the embodiments shown in FIGS. 1-4.

### DETAILED DESCRIPTION

In the following detailed description and the attached drawings and appendices, numerous specific details are set forth to provide a thorough understanding of the present disclosure. However, those skilled in the art will appreciate that the present disclosure may be practiced, in some instances, without such specific details. In other instances, well-known elements have been illustrated in schematic or block diagram form in order not to obscure the present disclosure in unnecessary detail. Additionally, for the most part, specific details, and the like, have been omitted inasmuch as such details are not considered necessary to obtain a complete understanding of the present disclosure, and are considered to be within the understanding of persons of ordinary skill in the relevant art.

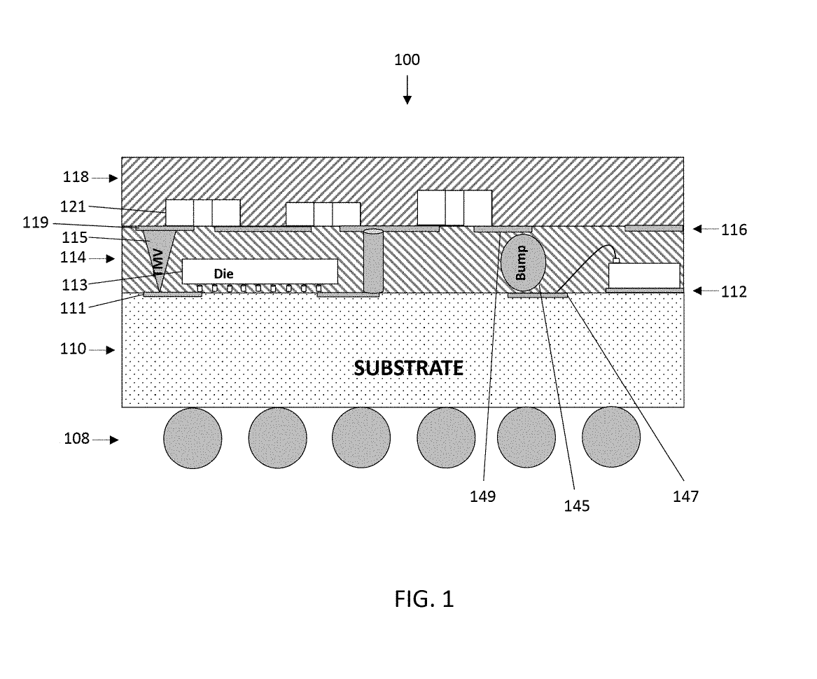

With reference to FIG. 1, an electronic device 100 is now described. The electronic device 100 includes a substrate or support 110 on top of a ball grid array (BGA) 108. A first interconnect layer 112 is formed on the substrate 110.

An integrated circuit die 113 is disposed on the substrate 110, and is electrically coupled to the BGA 108 through the substrate 110. Formed on the top surface of the substrate 110 is an electrical contact area 111 of the first interconnect layer 112, a portion of which is coupled to at least one electrical contact of the die. This electrical contact area 111 may be coupled to ground.

A first molding layer 114 (for example, formed from epoxy) encapsulates the die 113 and first interconnect layer 112, sealing against the substrate 110. A second interconnect layer 116 is formed on the top surface of the first molding layer 114. The second interconnect layer 116 has a second electrical contact area 119 formed therein.

A through mold via 115 extends through the first molding layer 114, electrically coupling the second electrical contact area 119 to the first electrical contact area. Those skilled in the art will recognize that instead of a through mold via 115, a conductive column or conductive bump may instead be used to electrically couple the second electrical contact area 119 to the first electrical contact area.

A passive ESD protection component 121 is disposed over the second interconnect layer 116 and is electrically coupled to the second electrical contact area 119. The passive ESD protection component 121 serves to protect the die 113 from ESD events. A second molding layer 118 (for example, formed from epoxy) encapsulated the passive ESD protection component 121 and second interconnect layer 116, sealing against the first molding layer 114.

The vertical stacking of the passive ESD protection component 121 serves to save space about the periphery of the substrate 110, thereby potentially limiting the size of the perimeter of the electronic device 100, rendering it more compact and more suitable for certain uses.

Formation of the electronic device 100 will now be described. First, the first interconnect layer 112 is formed on the substrate 110 by suitable processes, such as by deposition, electroplating, or lithography. Thereafter, the die 113 is placed or attached. If a bump or column is to be used, the bump or column is pre-formed and then placed or attached. Then, the first molding layer 114 is deposited. The through mold via 115 is formed via laser drilling into the first molding layer 114, depositing solder paste into the void formed by the laser drilling. In some application, rather than solder paste, the through mold via 115 may be formed by electroplating after the laser drilling.

The second interconnect layer 116 is then formed on the top surface of the first molding layer 114, for example by etching the pattern for the second interconnect layer 116 into the first molding layer 114 and then depositing solder paste, or by the laying of copper foil, or the spraying of conductive material. Thereafter, the passive ESD protection device 121 is placed or attached, and the second molding layer 118 is deposited. The electronic device 100 is ultimately heated so as to melt solder paste.

The device 100 as formed provides for space saving through vertical stacking, rendering it more suitable for use in certain application. In some applications however, a different vertical stacking arrangement may be desired.

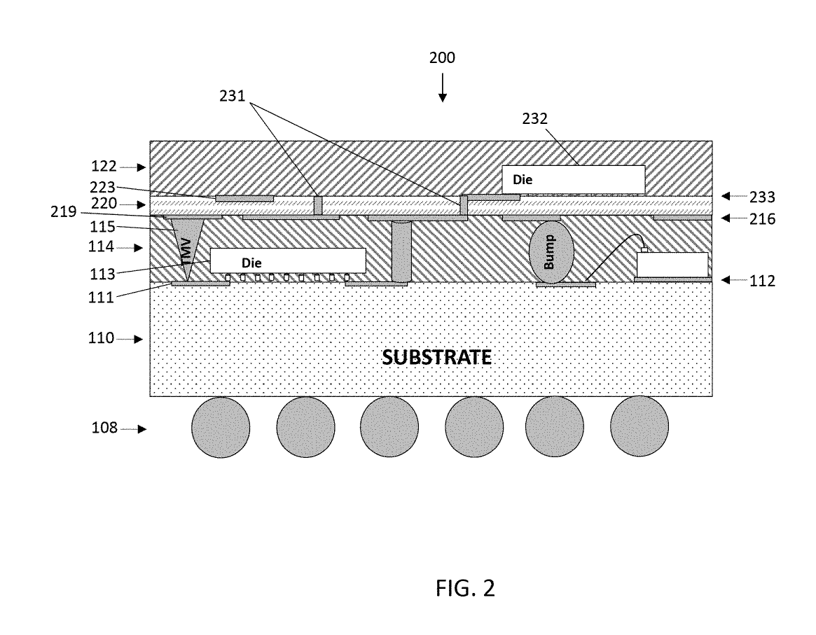

One such application is described now with reference to FIG. 2. Here, the electronic device 200 includes the substrate 110 on top of the ball grid array (BGA) 108. The first interconnect layer 112 is formed on the substrate 110.

The integrated circuit die 113 is disposed on the substrate 110, and is electrically coupled to the BGA 108. Formed on the top surface of the substrate 110 is the electrical contact area 111 of the first interconnect layer 112, a portion of which is coupled to at least one electrical contact of the die 113. The first molding layer 114 encapsulates the die 113 and first interconnect layer 112, sealing against the substrate 110.

A polyimide tape 220 with interconnect layers 216 and 233 on opposite sides thereof is disposed on the upper side of the first molding layer 114. The interconnect layers 216 and 233 are joined by vias 231. A second die 232 is placed on the interconnect layer 233, and a second molding layer 122 seals the die 232 to the interconnect layer 233.

Formation of the electronic device 200 will now be described. First, the first interconnect layer 112 is formed on the substrate 110 by suitable processes, such as by deposition, electroplating, or lithography. Thereafter, the die 113 is placed or attached. If a bump or column is to be used, the bump or column is pre-formed and then placed or attached. Then, the first molding layer 114 is deposited. The through mold via 115 is formed via laser drilling into the first molding layer 114, depositing solder paste into the void formed by the laser drilling. In some application, rather than solder paste, the through mold via 115 may be formed by electroplating after the laser drilling.

The tape 220 is then rolled into place over the top side of the molding layer 114. In some applications, the vias 231 are already in place within the tape 220, although in other applications, the vias 231 are then formed via laser drilling and solder paste deposition or electroplating. The die 232 is then placed on the interconnect layer 233 (or it is attached to the tape 220 prior to the tape being mounted), and the second molding layer 122 is deposited. The electronic device 200 is ultimately heated so as to melt solder paste.

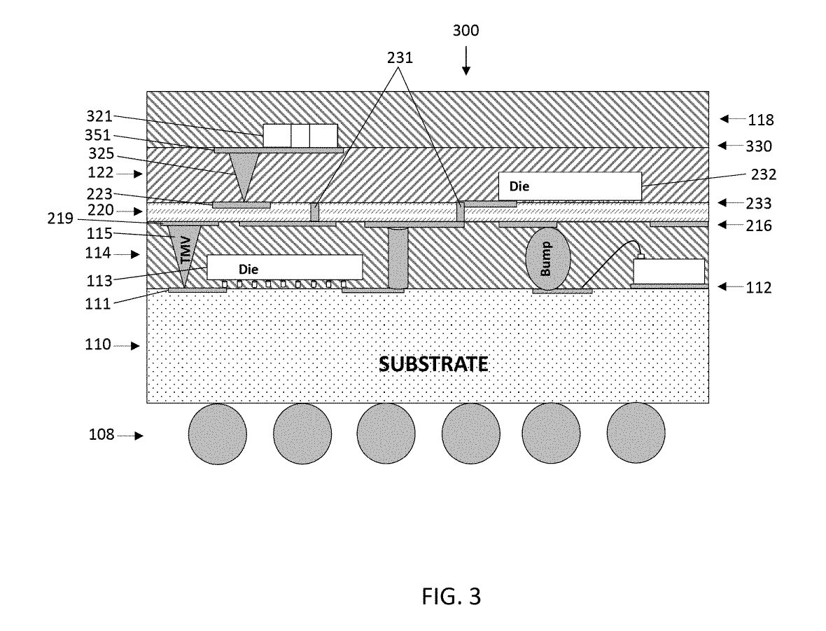

A further embodiment is now described with reference to FIG. 3. Here, the electronic device 300 includes the substrate 110 on top of the ball grid array (BGA) 108. The first interconnect layer 112 is formed on the substrate 110.

The integrated circuit die 113 is disposed on the substrate 110, and is electrically coupled to the BGA 108. Formed on the top surface of the substrate 110 is the electrical contact area 111 of the first interconnect layer 112, a portion of which is coupled to at least one electrical contact of the die 113. The first molding layer 114 encapsulates the die 113 and first interconnect layer 112, sealing against the substrate 110.

A polyimide tape 220 with interconnect layers 216 and 233 on opposite sides thereof is disposed on the upper side of the first molding layer 114. The interconnect layers 216 and 233 are joined by vias 231. A second die 232 is placed on the interconnect layer 233, and a second molding layer 122 seals the die 232 to the interconnect layer 233.

An interconnect layer 330 is formed in the top surface of the second molding layer 122, and a through molding via 325 connects the interconnect layer 330 to the interconnect layer 233. A passive ESD protection component 321 is coupled to the interconnect layer 330. A third molding layer 118 is formed on the top surface of the second molding layer 122.

Formation of the electronic device 200 will now be described. First, the first interconnect layer 112 is formed on the substrate 110 by suitable processes, such as by deposition, electroplating, or lithography. Thereafter, the die 113 is placed or attached. If a bump or column is to be used, the bump or column is pre-formed and then placed or attached. Then, the first molding layer 114 is deposited. The through mold via 115 is formed via laser drilling into the first molding layer 114, depositing solder paste into the void formed by the laser drilling. In some application, rather than solder paste, the through mold via 115 may be formed by electroplating after the laser drilling.

The tape 220 is then rolled into place over the top side of the molding layer 114. In some applications, the vias 231 are already in place within the tape 220, although in other applications, the vias 231 are then formed via laser drilling and solder paste deposition or electroplating. The die 232 is then placed on the interconnect layer 233 (or is attached to the tape 220 prior to attachment of the tape), and the second molding layer 122 is deposited. The through molding via 325 is then formed via laser drilling and solder paste deposition, and the interconnect layer 330 is formed by suitable processes, such as by deposition, electroplating, or lithography. The passive ESD protection device 321 is then placed on the conductive area 351 of the interconnect layer 330, and the third molding layer 118 is deposited. The electronic device 300 is ultimately heated so as to melt the solder paste.

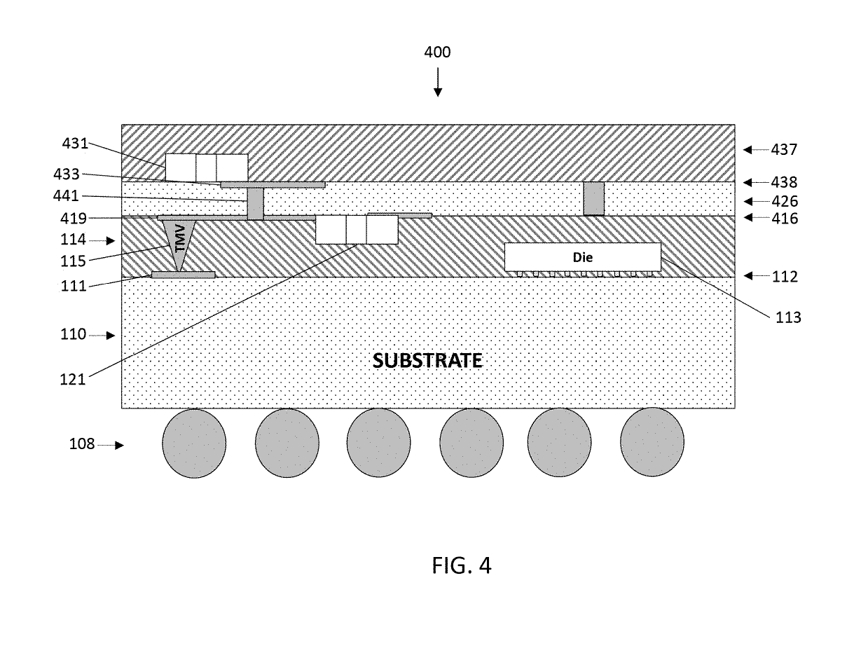

Another embodiment is now described with reference to FIG. 4. Here, the electronic device 400 includes a substrate 110 carried by a ball grid array 108. Formed on the substrate 110 is the interconnect layer 112, which includes the conductive area 111. The die 113 is placed on the substrate 110 and is electrically coupled to the ball grid array 108.

A first molding layer 114 is disposed on the top surface of the substrate 110. A second substrate 426 that is thinner than the first substrate 110 is disposed on the top surface of the first molding layer 114. The second substrate 426 has interconnect layers 416 and 438 disposed on opposite sides thereof and coupled by vias 141. The interconnect layer 416 includes a conductive area 419, and the interconnect layer 438 includes a conductive area 433. A passive ESD protection component 121 is disposed within the first molding layer 114 and coupled to the conductive area 419. A passive ESD protection component 431 is disposed on the interconnect layer 438 and coupled to the conductive area 433. A second molding layer 437 seals against the passive ESD protection component 431 and interconnect layer 438.

Formation of the electronic device 400 will now be described. The interconnect layer 112 is formed on the substrate 110 by suitable processed, and the die 113 is then placed. Thereafter, the first interconnect layer 112 is deposited on the substrate 110. The first molding layer 114 is then deposited, and the through mold via 115 is formed via laser drilling and solder paste or electroplating. A cavity is then formed to accept the passive ESD protection component 431.

The substrate 426 is formed separately, and the interconnect layers 416 and 438 are formed opposing sides thereof by suitable processed and electrically coupled by the vias 441. The passive ESD protection component 121 is then placed on the interconnect layer 416, and the second substrate 426 is then placed on the first molding layer 114. The passive ESD protection component 431 is then placed on the conductive area 433, and the second molding layer 437 is deposited on the top surface of the second substrate 426 to seal the passive ESD protection component 431 against the interconnect layer 438. The electronic device 400 is ultimately heated to melt solder paste.

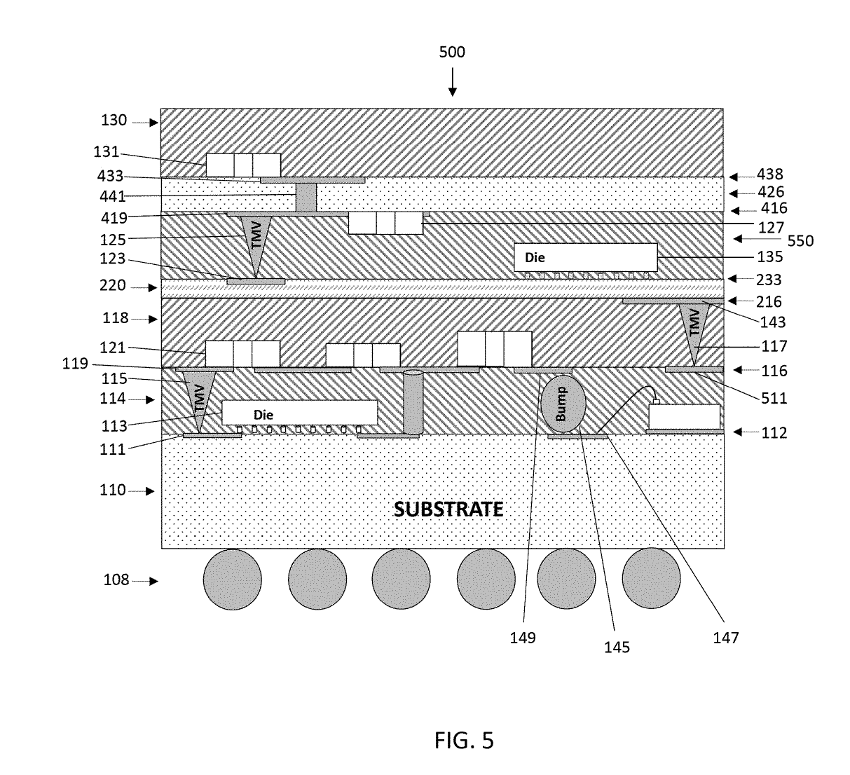

Yet another embodiment is now described with reference to FIG. 5. Here, the substrate 110 is disposed on the ball grid array 108. The first interconnect layer 112 is formed on the substrate 110, and includes the conductive areas 111 and 147. The die 113 is disposed on the substrate 110 and is electrically coupled to the conductive area 111. A bump 145 is disposed on the conductive area 147. The first molding layer 114 is disposed on the substrate 110. An interconnect layer 116 is formed on the top portion of the first molding layer 114. A through molding via 115 couples the interconnect layer 116 to the interconnect layer 112.

A passive ESD protection component 121 is disposed on the conductive area 119 of the interconnect layer 116. A second molding layer 118 is formed on the top side of the first molding layer 114. A through molding via 117 is formed within the second molding layer 118.

A layer of polyimide tape 220 having opposing interconnect layers 216 and 233 is disposed on the second molding layer 118. A conductive area 143 of the interconnect layer 216 is coupled to the conductive area 116 by the through molding via 117.

A second die 135 is disposed on the tape 220, and a third molding layer 550 is formed on the tape 220. A through molding via 125 is formed within the third molding layer 550 and coupled to the conductive area 123.

A second substrate 426 having interconnect layers 438 and 416 formed on opposite sides is disposed on the third molding layer 550. A passive ESD protection component 127 is connected to the conductive area 419 of the interconnect layer 416 and is located within the third molding layer 550. A via 441 couples the conductive area 419 to the conductive area 433 of the interconnect layer 438. A passive ESD protection component 131 is coupled to the conductive area 433, and a fourth molding layer 130 seals the passive ESD protection component 131 against the second substrate 426.

The formation of the electronic device 500 is now described. The interconnect layer 112 is formed on the substrate 110, and then the die 113 and bump 145 are placed. The first molding layer 114 is then deposited, and the through molding via 115 is then formed via laser drilling and solder paste or electroplating. The interconnect layer 116 is then formed by suitable techniques as described above, the passive ESD protection component 121 is places, and the second molding layer 118 is then deposited. The through molding via 117 is then formed, and the tape 220 is then placed.

Thereafter, the die 135 is placed, and the third molding layer 550 is deposited. A cavity is formed to receive the passive ESD protection component 127, and the through molding via 125 is formed through the third molding layer 550. The second substrate 126, which is pre-formed to have the interconnect layers 416 and 438 coupled together by the via 441, and to have the passive ESD protection components 131 and 127 thereon, is then placed on the third molding layer 550. The fourth molding layer 130 is then deposited. The electronic device 500 is then heated to melt solder paste.

It should be appreciated that any suitable formation methods may be used. Also, any number of molding layers, interconnect layers, dielectric layers, substrates, die, other electronic devices, passive ESD protection devices, and through molding vias may be used. Indeed, the teachings of this disclosure are applicable to any such arrangement utilizing the stacking of molding layers, some of which contain passive ESD protection devices. Through molding vias haves been described to form electrical vertical connections through the various molding layers. However, any other electrical vertical connections may be used, like e.g. copper pillars or bumps, with molding thickness chosen so as to expose an upper portion of the copper pillars or bumps.

Although the preceding description has been described herein with reference to particular means, materials and embodiments, it is not intended to be limited to the particulars disclosed herein; rather, it extends to all scope of the appended claims.

1. An electronic device, comprising:
a substrate having a conductive area formed thereon;
a first molding level stacked on the substrate;
a die formed on the substrate and within the first molding level;
a second molding level stacked on the first molding level;
at least one passive component within the second molding level; and
a conductive structure extending between the second molding level and the substrate and electrically coupling the at least one passive component to the conductive area.

2. The electronic device of claim 1, wherein the at least one passive component comprises an electrostatic protection device.

3. The electronic device of claim 1, further wherein the conductive area is formed on the substrate adjacent the die; and wherein the die is also electrically coupled to the conductive area.

4. The electronic device of claim 1, wherein the conductive structure comprises one of a through mold via, a conductive column, or a conductive bump.

5. The electronic device of claim 1, further comprising copper foil coupling the conductive structure to the at least one passive component.

6. The electronic device of claim 1, further comprising conductive tape coupling the conductive structure to the at least one passive component.

7. The electronic device of claim 1, further comprising:
a dielectric layer stacked on the second molding level and having a second conductive area formed therein;
a third molding level stacked on the dielectric layer;
a second die within the third molding level and disposed on the dielectric layer;
at least one second passive component disposed within the third molding level;
a second conductive structure extending through the third molding level and electrically coupling the at least one second passive component to the second conductive area.

8. The electronic device of claim 7, wherein the second molding level has a third conductive area disposed therein; and further comprising a third conductive structure extending through the second molding level and electrically coupling the second conductive structure to the third conductive area.

9. The electronic device of claim 8, wherein the third conductive area is electrically coupled to the at least one passive component.

10. The electronic device of claim 1, wherein the first and second molding levels comprise epoxy.

11. A method of making an electronic device, comprising:
forming a conductive area on a substrate;
disposing a die on the substrate;
depositing a first molding layer over the substrate and the die;
disposing at least one passive component on the first molding layer;
forming a conductive structure extending between the at least one passive component and the conductive area on the substrate;
depositing a second molding layer over the first molding layer, the at least one passive component, and the conductive structure.

12. The method of claim 11, wherein forming the conductive structure comprises laser drilling into the first molding layer to form a cavity and depositing solder paste into the cavity.

13. The method of claim 12, wherein the cavity is formed to be a through mold via.

14. The method of claim 12, wherein the cavity is formed to be a column.

15. The method of claim 12, wherein the cavity is formed to be a bump.

16. The method of claim 11, further comprising disposing copper foil on the first molding layer prior to disposing of the at least one passive component; and further comprising electrically coupling the conductive structure to the at least one passive component using copper foil.

17. The method of claim 11, further comprising disposing conductive tape on the first molding layer prior to disposing of the at least one passive component; and further comprising electrically coupling the conductive structure to the at least one passive component using conductive tape.

18. The method of claim 11, further comprising spraying a conductive material on the first molding layer prior to disposing of the at least one passive component; and further comprising electrically coupling the conductive structure to the at least one passive component using the conductive material.

19. The method of claim 11, further comprising:
depositing a dielectric layer on the second molding level;
forming a second conductive area in the dielectric layer;
depositing a third molding layer on the dielectric layer;
disposing at least one second passive component within the third molding layer; and
forming a second conductive structure extending between the at least one second passive component and the second conductive area.

20. The method of claim 19, further comprising forming a third conductive area in the second molding layer, and forming a third conductive structure extending between the second molding layer to electrically couple the second conductive structure to the third conductive area.

21. The method of claim 20, further comprising electrically coupling the third conductive area to the at least one passive component.
